(19) United States
(12) Patent Application Publication
(10) Pub. No.: US 2017/0279407 A1
(43) Pub. Date: Sep. 28, 2017

(54) PHOTOVOLTAIC MODULE WITH INTEGRATED LIGHT-DIRECTING STRUCTURE ON THE BASIS OF TOTAL INTERNAL REFLECTION

(71) Applicant: JOANNEUM RESEARCH FORSCHUNGSGESELLSCHAFT MBH, Graz (AT)

(72) Inventors: Gerhard PEHARZ, Gleisdorf (AT); Bernhard LAMPRECHT, Graz (AT); Christian SOMMER, Graz (AT); Wolfgang NEMITZ, Pischelsdorf (AT); Volker SCHMIDT, Pischelsdorf (AT)

(21) Appl. No.: 15/505,145

(22) PCT Filed: Aug. 18, 2015
(86) PCT No.: PCT/AT2015/000110

§ 371 Date: Feb. 20, 2017

(30) Foreign Application Priority Data
Aug. 20, 2014 (AT) A 647/2014

(51) Int. Cl. H02S 40/22; H01L 31/05; H01L 31/048

(52) U.S. Cl. CPC H02S 40/22; H01L 31/0481; H01L 31/0504

(57) ABSTRACT

In a photovoltaic module (1) comprising a plurality of electrically interconnected solar cells (2) embedded in an encapsulation film(5) at least on one side and arranged at a distance from one another, and, if appropriate, a rear-side film (6) and a light-transmissive cover plate, light-guiding films forming prism-like structures (4) are integrated in regions of the photovoltaic module (1) that are free of solar cells (2) and the prism-like structures (4) and complementary air and gas pockets (8) are arranged alternately. The prism-like structures (4) of the light-guiding films are arranged in such a way that light impinging on the light-guiding, prism-like structures (4) is guided in the direction of the solar cells (2). An encapsulation film (5) is arranged on both sides of the solar cell and the light-guiding film forming prism-like structures (4) is arranged within the encapsulation film (5), and the light-guiding films forming prism-like structures (4) are covered, if appropriate, by a transparent polymer film (6, 12).

The present invention relates to a photovoltaic module comprising a plurality of electrically connected solar cells arranged spaced apart from one another and embedded on at least one side in an encapsulation material, in particular an encapsulation film, as well as possibly a back-side film and a light-permeable cover plate.

Photovoltaic modules generally comprise a plurality of solar cells that are electrically connected with one another and that are arranged in a planar manner in the interior of the photovoltaic module. Between the individual solar cells and in particular on the edge of the photovoltaic module there are areas that are not covered by solar cells and thus are not available for using solar energy. The gaps between the individual cells are generally relatively narrow, but the performance of the modules is limited by the normally approximately 2 cm-wide edge that is not electrically active and that currently is also not usable, so that a total of only about 90% of the module surface is covered with solar cells and available for converting sunlight to energy, which overall is not an insignificant unused surface area. To minimize such a loss of convertible solar energy, recently a number of different solutions have been suggested that use structured films with which the reflection of the sunlight is intended to be supported in those areas in which there are no solar cells to areas in which there are solar cells in order to maximize the energy yield.

For instance, U.S. Pat. No. 5,994,641 describes a photovoltaic module in which a back-side film is used that is provided with light-reflecting means, in particular with a symmetrical, V-shaped saw-tooth profile, and the incident light on its inclined surface is intended to be reflected to the areas provided with solar cells. The drawback of such a solution is that the V-shaped saw-tooth profile is embodied symmetrical and that light is reflected both to the center of the photovoltaic module and to its exterior, so that again only a small portion of the light that does not strike the solar cells directly may be reflected onto them and is available for producing energy.

Another such solution is described in WO 2010/096700, in which a micro-embossed, reflective, optical film is arranged in those areas of the photovoltaic module that are not covered by solar cells. In this solution, as well, foils or films are used in which essentially regular prism-shaped structures are embossed and with which it is attempted to obtain, by means of reflection, the light incident on the areas of the photovoltaic module that are not covered with solar cells so that it may be converted to electrical energy in that there is an attempt to reflect said incident light onto the solar cells present in the photovoltaic module. In this document, as well, structures that are used essentially have the shape of symmetrical prisms and it is thus not assured that light is reflected solely in a desired direction to the solar cells. However, in all of the currently known systems it is necessary for the structured films to be provided with a reflective coating, especially a metal coating.

Known from JP 2006 049487A are photovoltaic modules having a plurality of electrically connected, solar cells that are arranged spaced apart from one another and at least partially embedded in encapsulation films. In these photovoltaic modules, encapsulation is embodied such that it does not extend to the edge of a cover plate or back-side covering in order to be able to maintain the functionality of the photovoltaic module following a lamination process. The goal of this document is to embody the encapsulation of the prism structure such that the prisms are not completely enclosed by encapsulation material in order to be able to maintain system functionality.

Furthermore, a solar module is known from EP 2 571 062 B1 in which a solar cell unit is arranged on a back-side plate such that a bottom surface of the solar cell faces the back-side plate and the light-receiving side is embodied opposite the bottom surface.

The objective of the present invention is to make available a photovoltaic module with which it is possible not only to use the light striking the individual solar cells for conversion to energy, but also in particular to reflect the light that strikes the free edge areas of the photovoltaic module such that said light strikes a solar cell in the interior of the module and may be used for conversion to electrical energy and thus the energy yield of the photovoltaic module is significantly increased compared to conventional photovoltaic modules.

For attaining this object, the inventive photovoltaic module is essentially characterized in that light-directing films embodying prism-like structures are integrated in areas of photovoltaic modules that are free of solar cells, in that the prism-like structures of the light-directing films are arranged such that the prism-like structures and complementary air and gas inclusions are arranged alternating, in that light incident on the light-directing prism-like structures is directed toward the solar cells, in that an encapsulation film is arranged on both sides of the solar cell and the film embodying the light-directing, prism-like structures is arranged in the interior of the encapsulation film, and in that the foils embodying the light-directing prism-like structures are possibly covered by a transparent polymer film. Since films embodying light-directing prism-like structures are integrated into the photovoltaic module in areas free of solar cells, elements are available that can reflect incident light. Furthermore, due to the embodiment as prism-like structures, a targeted reflection is made possible by the embodiment of very specifically shaped reflection surfaces. Furthermore, since the prism-like structures of the light-directing films are arranged such that light incident on the light-directing prism-like structures is directed toward the solar cells, it is assured that light that is incident on the edge areas of the photovoltaic module does not remain unused, either, but instead is reflected toward the center of the photovoltaic module, where it is incident on a solar cell in which the light energy is converted to electrical energy, so that the energy yield of the photovoltaic module overall is increased to nearly 100% of the possible energy yield. Alternating areas with air and gas inclusions that have a geometry complementary to the prism-like structure of the film are embodied in particular in those areas where the prism-like structures of the light-directing films are arranged. Due to these likewise prism-like structures it is possible to direct light without it being necessary to add a reflective coating, such as a metal layer, onto the prism-like structures of the light-directing film. One essential advantage of the inventive photovoltaic module is that a reflective coating that has to be applied to the prism-like structures in order to ensure that the incident light is reflected is not necessary, so that the module may be configured in a significantly simpler and more cost-effective manner.

As is the case with the invention, since the photovoltaic module is embodied such that encapsulation films are arranged on both sides of the solar cells, the security of the module is further enhanced because in particular the connections or conductors required for the electrical line are covered and insulated by the encapsulation film. Moreover, such an encapsulation film ensures that mechanical damage to the photovoltaic module may be prevented. In addition, the film embodying light-directing, prism-like structures is provided in the interior of the encapsulation film in order to prevent mechanical damage to any of the elements and in particular to protect the electrical connection or the conductors both from unintended touching and also from damage, to the extent possible.

Furthermore, since if necessary the films embodying light-directing, prism-like structures are covered by a transparent polymer film, it is assured that the fine structures in the light-directing film are not damaged by mechanical influences and it is further assured that, especially when a photovoltaic module is constructed in layers or like a sandwich, the air-filled hollow spaces, especially prism-shaped hollow spaces, are filled and thus rendered unusable.

As is found in a refinement of the present invention, since the photovoltaic module is embodied such that the prism-like structures are embodied as oblique structures similar to triangular prisms having an essentially right angle, a type of saw-tooth profile is provided in which those sides that are adjacent to the essentially right angle do not contribute to a reflection, since the one of these surfaces acts as a base surface and the other will reflect only very little incident light due to the normally essentially perpendicular incidence of light. The primary reflection of the light occurs at the third surface of the oblique prism-like structures, which third surfaces are inclined relative to a base surface or a back-side plate of the photovoltaic module, and in which surfaces, due to the physico-chemical properties of the material that is available for such purposes, it is assured that essentially all light incident to this surface of a photovoltaic module, which surface is inclined to the horizontal and vertical, is reflected to the center of the module and thus to the solar cells. Using such a structure it is possible to convert essentially all of the light to electrical energy and the losses known from the prior art may be drastically reduced from approximately 10% to a maximum of 1.5% of the incident light.

As is found in a refinement of the present invention, since the photovoltaic module is embodied such that a surface of the prism-like structure opposing the essentially right angle is embodied as a surface having a flat surface, a convex curvature, a concave curvature, or a convex/concave curvature. Because of the fact that, due to such a structural embodiment of the oblique prisms, especially that surface opposing the right angle is embodied as a surface having a flat surface, a surface having convex curvature, a surface having concave curvature, or a surface having a convex/concave curvature, and due to the specific arrangement of these oblique prisms such that the surface having such an inclined flat surface, convex curvature, concave curvature, or convex/concave curvature is arranged oriented toward a center of the photovoltaic module, it is possible to reliably reflect incident light at areas that are not covered by solar cells to the center of the photovoltaic module, and thus to improve the light yield overall.

Particularly efficient reflection, and in particular particularly low loss of incident light and thus a high energy yield, is attained with the inventive photovoltaic module in that a flank angle of the prism-like structure is selected between 25° and 65° and a preventative flank angle of the prism-like structure is selected between 80° and 90°. Due to the selection of such a flank angle of the prism-like structure and of a preventative flank angle of the same, the light and energy yield from perpendicularly incident light is maximized, since it is directed or reflected asymmetrically only toward the center of the photovoltaic module.

Since the photovoltaic module is refined such that the prism-like structures are embodied having a film between 100 nm and 100 mm, especially 10 μm to 300 μm, structures are provided that assure universal use of the photovoltaic modules.

Another advantage of such an arrangement of a film having a structuring, which film has structures similar to an oblique prism, is that, due to the total internal reflection that occurs in the film, the light is directed in the desired direction to the center, so that an additional reflective coating is not necessary. Using such an embodiment, the inventive photovoltaic module is not only more cost-effective, but also in particular is safer, since electrical current may no longer be conducted from the cells via a reflective coating, in particular a metal coating, to the edge of the photovoltaic module, and thus any safety risks, which could involve electric shock or the like, are eliminated.

As is found in a refinement of the present invention, since the back-side film has the light-directing, prism-like structures integrated on its side facing the solar cells, a further simplification of the photovoltaic module is attained, in particular, it is possible to embody in a single layer those light-directing, prism-like structures that ensure that light striking them is directed toward the solar cells, so that the light yield may be improved significantly.

As is found in a refinement of the invention, to design the device as simple as possible the photovoltaic module is refined such that the film embodying the light-directing, prism-like structures and the polymer film sealing or covering these structures are embodied from the same material, selected from polyethylene terephthalate (PET), polyurethane (PU), polyethylene (PE), polyurethane acrylate (PUA), polyamide, polytetrafluorethylene (PTFE), polystyrene (PS), polycarbonate (PC), polyethylene naphthalate (PEN), polymethyl methacrylate (PMMA), or silicone. With such an embodiment, the most similar materials possible may be selected that differ only in their refractive index or geometric structure with which the reflectivity is attained, are used, so that materials that differ from one another as little as possible may be used, but at the same time it is assured that there will be complete reflection on the surface of the light-directing film having structures similar to oblique prisms. To prevent, to the extent possible, any losses in the light yield, according to a refinement of the invention the photovoltaic module is embodied such that a transparent polymer film in the range of 300 nm and 2500 nm, in particular 350 nm to 1200 nm, made of a material selected from ethylene vinylacetate (EVA), polyvinylbutyral (PVB), silicone, thermoplastic polymers (TPE), or polyethylene (PE) is used as encapsulation film.

Transmission is improved since a plate made of low-iron glass is used as the cover plate of the photovoltaic module. Another improvement in the transmission is assured in that this low-iron glass is embodied completely smooth, without any texture, and preferably has a thickness between 1 nm and 60 nm, in which thickness range the glass provides sufficient strength without negatively affecting the optical and light-directing properties of the entire structure. Needless to say, naturally any colored glass may be used or specific surface textures may be used, wherein in this case, however, a somewhat reduced transmission must be accepted.

As is found in a refinement of the invention, since an electrical insulation film, especially an insulation film having a coefficient of reflectivity of R>90% in a wavelength range of 350 nm to 1200 nm, is used as the back-side film, it is assured that no light at all penetrates the photovoltaic module and in particular all of the incident light is reflected back from the back-side film into the photovoltaic module in order to further improve the energy yield.

As is found in a refinement of the invention, because the encapsulation film is embodied as a reflective barrier layer, especially electrical insulation film, it is assured that the solar cell, just like the light-directing, prism-like structures, are insulated from other layers, in particular are electrically insulated, which significantly enhances operating safety.

For a particularly simple structure of the photovoltaic module in terms of material, the latter is essentially characterized in that the film embodying the encapsulation film, the back-side film, and the light-directing, prism-like structures is embodied as reflective, electrical insulation films that reflect more than 90% of the light in a wavelength range between 350 nm and 1200 nm. Such a structure ensures that, on the one hand, as much light as possible is reflected in the critical range of 350 nm to 1200 nm, and, on the other hand, ensures that the only light reflected is the light that is necessary for proper functioning of the photovoltaic module. In any event, absorption of light is reliably prevented.

Furthermore, since not only is one cover plate embodied as glass, but also the back-side film is embodied as glass plate, the technical structure is further simplified and in particular the photovoltaic module's resistance to mechanical damage is further increased.

The invention shall be described in greater detail in the following using exemplary embodiments depicted in the drawings.

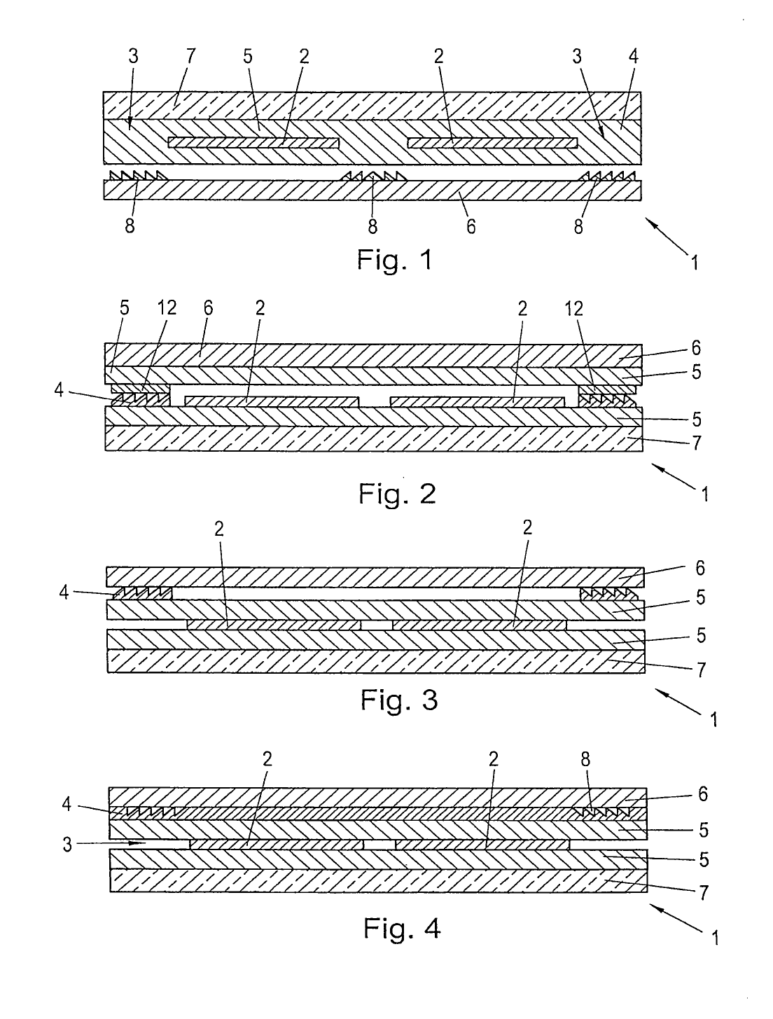

FIG. 1 depicts a structure of a photovoltaic module according to the invention;

FIG. 2 depicts one option for arranging the elements embodying the photovoltaic module;

FIG. 3 depicts one option for arranging the elements embodying the photovoltaic module;

FIG. 4 depicts another option for arranging the elements embodying the photovoltaic module;

FIG. 5 is a schematic depiction of light-directing, prism-like structures according to the invention;

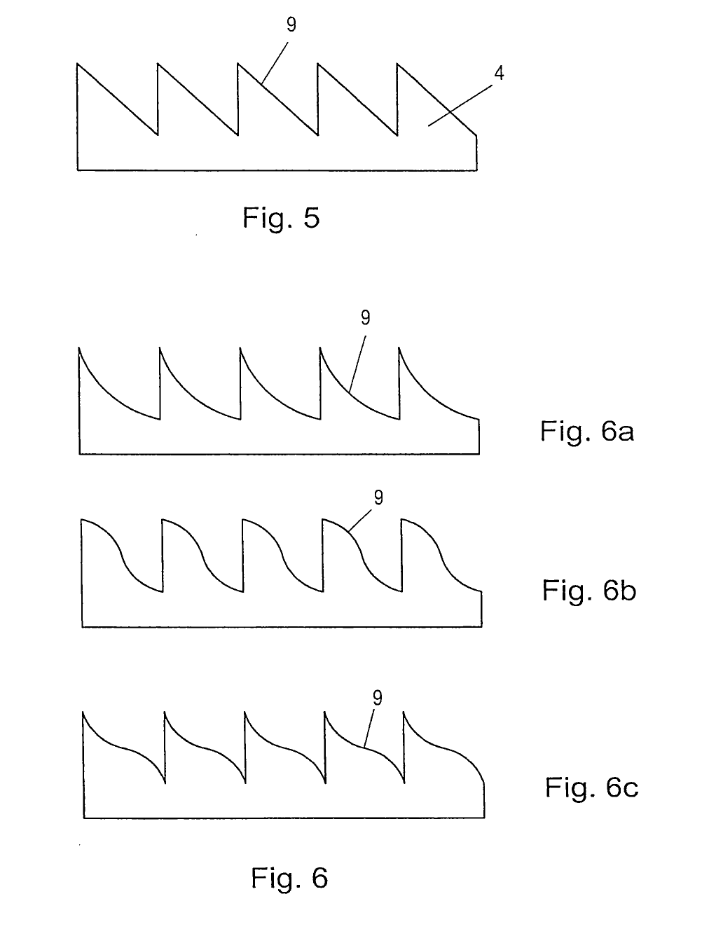

FIG. 6 depicts three additional possible forms of the light-directing, prism-like structures that may be used in a photovoltaic module according to the invention; and,

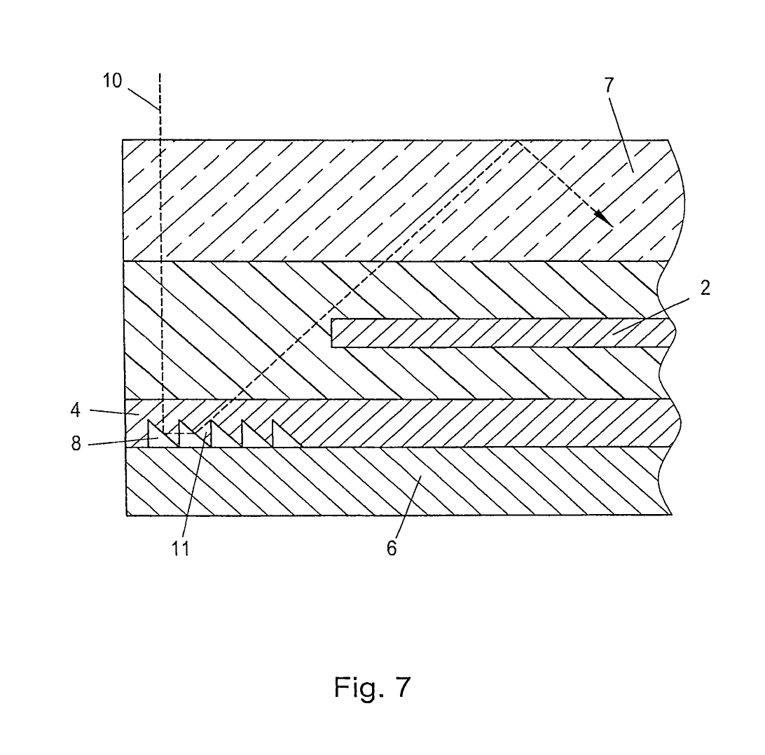

FIG. 7 depicts the outer left edge area of the photovoltaic module from FIG. 1, in which, in addition to the layer structure, the path of an incident light beam is illustrated.

FIG. 1 illustrates a photovoltaic module 1 according to the invention in detail. Two solar cells 2 that are arranged spaced apart from one another are depicted schematically in this photovoltaic module 1. In the embodiment of the photovoltaic module 1 according to FIG. 1 it may be seen that an edge area 3 of the photovoltaic module 1 does not contain any solar cells 2 and this edge area 3 cannot contribute to converting sunlight to energy. In order to convert as much sunlight striking this edge area 3 to energy as possible, in the depiction of FIG. 1 a plurality of light-directing structures 4 that have the shape of oblique prisms are provided in both edge areas 3 of the photovoltaic module 1. When light strikes these essentially prism-like structures 4 of the light directing elements perpendicularly, it is reflected internally totally toward an interior of the photovoltaic module 1, refracted on one of the adjacent prisms, and then finally totally reflected on the interface of the glass plate 7, functioning as cover plate, with the ambient air, so that this light is available for a further conversion to energy, and is not unavailable for conversion to energy like photovoltaic modules according to the prior art. In order to protect the solar cells 2 of the photovoltaic module 1 according to FIG. 1 from any destruction, as may be seen from FIG. 1 they are embedded in an encapsulation film 5. To complete the photovoltaic module 1, the latter is further held by a back-side plate 6 and covered with a glass plate 7. Finally, air 8 is added between the plurality of oblique prisms 8 in order to make it possible to direct light without providing a reflective coating.

The back-side plate or back-side film 6 is an electrical insulation film that has a relatively high coefficient of reflectivity for sunlight in order to reflect sunlight that has penetrated to the back-side plate 6 and have it available for further conversion to energy in the interior of the photovoltaic module 1.

The depiction according to FIG. 2, in which the reference numbers from FIG. 1 are essentially retained, illustrates one option for how a photovoltaic module 1 according to the invention may be constructed or produced.

First an encapsulation film 5 is applied to the entire surface of a glass plate 7, and in a next step the photovoltaic module 1 and the films with prism-like structures 4 are applied to said encapsulation film 5. As may clearly be seen in FIG. 2, the films with the prism-like structures 4 are applied in those areas of the photovoltaic module that are not covered with solar cells 2 and are oriented toward the plate 7, and a step, and a step according to which the prism-like structures 4 are covered by a protective film 12. In a further step, a further encapsulation film 5 and a back-side film 6 are applied to this layer 12. It is obvious that in order to attain a photovoltaic module as is depicted in FIG. 1, it is merely necessary to add a film with prism-like structures 4 in the area between the solar cells 2, which area is free of solar cells. In particular, the prism film 4 is enclosed with the encapsulation film 5 without the optical effect being destroyed, because in the required lamination process the encapsulation material, i.e. the film 5, cannot penetrate between the plate 6 and the structures 8 released by the prism film 4, because the prism structure 8 is protected by the film 12. For this reason it is possible to embody light-directing structures even in the interior of the module.

The back-side plate 6 may be embodied as a plate-like element or film-like element, both in the depiction according to FIG. 1 and that according to FIG. 2, wherein the back-side film may also be embodied integrally with the film having the prism-like structures 4 or may have the prism-like structures immediately on its side facing the solar cells 2.

FIG. 3 illustrates another option for constructing or producing a photovoltaic module according to the present invention.

In this depiction, as well, in a first step an encapsulation film 5 is applied to a glass plate 7, and in another step the solar cells 2 are applied to the encapsulation film 5 and then are covered by an encapsulation film 5. In the next step, the film with prism-like structures 4 is applied in those areas that are not covered by solar cells 2, wherein when this production method is used the protective film 12, which is absolutely necessary in the structure in FIG. 2 for protecting the prism-like structures, may be omitted. Then the photovoltaic module 1 is again covered using a back-side film or back-side plate.

In the depiction according to FIG. 4, the structure is essentially the same as that in FIG. 3, with the exception that after the second encapsulation film 5 is applied, the back-side film 6 is applied, on which back-side film 6 the prism-like structures 4 are already embodied, so that one work step may be saved.

In all of the embodiments according to the invention, the prism-like structures 4 are between 100 nm and 100 mm in height, wherein in the most common areas of application they are 10 μm to 300 μm in height.

The depiction in FIG. 5 illustrates one embodiment of the light-directing, prism-like structures 4, and it may be seen from them that these structures 4 essentially have the shape of an oblique prism, with an essentially right angle that corresponds to the preventative flank angle and that is normally between 80° and 90°. Consequently, in the same way the flank angle is selected to be between 25° and 65° , and the flank 9 facing the light is essentially oriented such that light perpendicularly incident on it is reflected toward the center.

FIG. 6 illustrates different shapes of the light-permeable, prism-like structures 4, wherein 6a depicts a structure that has a concavely curved flank with which light is reflected toward the center of a photovoltaic module 1. FIG. 6b illustrates a different embodiment of the light-permeable, prism-like structures 4, in which structures the flank 9 of the prism facing the light has one convex and one concave curvature, wherein the concave curvature is provided in the area of the base of the cylinder. Finally, FIG. 6c illustrates an embodiment of the light-permeable, prism-like structures 4 that have a concavely/convexly curved flank 9 and that also reflect light toward a center of a photovoltaic module 1.

FIG. 7, in which the reference numbers from FIG. 1 are retained, also depicts the path of a light beam 10 perpendicularly striking the photovoltaic module 1. The perpendicularly incident light beam is reflected at the interface of the structured film 4 with the air inclusion 8 embodied like a prism and directed one or a plurality of adjacent prisms, where the light beam is directed using refraction, especially when it strikes an inclined surface of one of the adjacent prisms 11, toward the glass plate 7, where the light is again reflected by total reflection toward the interior of the photovoltaic module 1 and strikes a solar cell 2 and is thus available to be converted to energy.

1-13. (canceled)

14. A photovoltaic module (1) comprising:
a plurality of electrically connected solar cells (2) arranged spaced apart from one another and embedded on both sides in an encapsulation film (5); and
a light-permeable cover plate,
wherein integrated in areas of the photovoltaic module (1) that are free of solar cells (2), are films embodying light-directing, prism-like structures (4),
wherein the prism-like structures (4) of the light-directing films are arranged such that light incident on the light-directing prism-like structures (4) is directed toward the solar cells (2),
wherein the prism-like structures (4) and complementary air and gas inclusions (8) are arranged alternating, and
wherein the photovoltaic module (1) comprises a back-side film (6) that is embodied integrally with the films embodying the light-directing, prism-like structures (4).

15. The photovoltaic module (1) of claim 14, wherein the films with prism-like structures (4) are added in the area between the solar cells (2) that is free of solar cells.

16. The photovoltaic module (1) of claim 14, wherein the prism-like structures (4) are embodied as oblique structures similar to a triangular prisms having an essentially right angle.

17. The photovoltaic module (1) of claim 16, wherein a surface of the prism-like structure (4) opposing the essentially right angle is embodied as a surface having a flat surface, a convex curvature, a concave curvature, or a convex/concave curvature.

18. The photovoltaic module (1) of claim 14, wherein a flank angle of the prism-like structure is selected between 25° and 65° and a preventative flank angle of the prism-like structure is selected between 80° and 90°.

19. The photovoltaic module (1) of claim 14, wherein the prism-like structures (4) are embodied having a height between 100 nm and 100 mm, especially 10 μm to 300 μm.

20. The photovoltaic module (1) of claim 14, wherein the encapsulation film (5) is arranged on both sides of the solar cells (2) and optionally the film embodying the light-directing, prism-like structures (4) is arranged in the interior of the encapsulation film (5).

21. The photovoltaic module (1) of claim 14, wherein the back-side film (6) has the light-directing, prism-like structures (4) integrated on its side facing the solar cells (2).

22. The photovoltaic module (1) of claim 14, wherein the film embodying the light-directing, prism-like structures (4) and the polymer film sealing these structures (4) are embodied from the same material, selected from polyethylene terephthalate (PET), polyurethane (PU), polyethylene (PE), polyurethane acrylate (PUA), polyamide, polytetrafluorethylene (PTFE), polystyrene (PS), polycarbonate (PC), polyethylene naphthalate (PEN), polymethyl methacrylate (PMMA), or silicone.

23. The photovoltaic module (1) of claim 14, wherein a transparent polymer film in the range between 300 nm and 2500 nm, in particular 350 nm to 1200 nm, made of a material selected from ethylene vinylacetate (EVA), polyvinylbutyral (PVB), silicone, or polyethylene (PE), is used as the encapsulation film.

24. The photovoltaic module (1) of claim 14, wherein a plate made of low-iron glass having a thickness between 1 nm and 60 mm is used as the cover plate (7).

25. The photovoltaic module (1) of claim 14, wherein an electrical insulation film, especially an insulation film having a coefficient of reflectivity of R>90% in a wavelength range of 350 nm to 1200 nm, is used as the back-side film (6).

26. The photovoltaic module (1) of claim 14, wherein the encapsulation film (5) is embodied as a reflective barrier layer, especially an electrical insulation film.

27. The photovoltaic module (1) of claim 14, wherein the film embodying the encapsulation film (5), the back-side film (6), and the light-directing prism-like structures (4) are embodied as reflective, electrical insulation films that reflect more than 90% of the light in a wavelength range between 350 nm and 1200 nm.

28. The photovoltaic module (1) of claim 14, wherein the back-side film (6) is embodied as a glass plate (7).
